(19) United States
(12) Patent Application Publication
(10) Pub. No.: US 2026/0371789 A1
(43) Pub. Date: Nov. 19, 2026

(54) VERTICALLY STACKED MICRODISPLAY PANEL AND METHOD FOR MANUFACTURING THE SAME

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/446,954

(22) Filed: Jan. 13, 2026

(30) Foreign Application Priority Data
Jan. 13, 2025 (KR) 10-2025-0004711
Jul. 17, 2025 (KR) 10-2025-0096891
Oct. 16, 2025 (KR) 10-2025-0149765

(51) Int. Cl. H10H 20/813; H10H 20/01

(52) U.S. Cl. CPC H10H 20/8131; H10H 20/017; H10H 20/018

(57) ABSTRACT

The present invention relates to a vertically stacked microdisplay panel including a back wafer having an upper surface on which a plurality of complementary metal oxide semiconductor (CMOS) electrode pads are arranged, a plurality of light-emitting diode (LED) stacks, each of which includes a plurality of light-emitting portions vertically stacked through a bonding layer and is arranged on one of the plurality of CMOS electrode pads, and a common electrode formed on the plurality of LED stacks, wherein the bonding layer includes a first bonding layer configured to bond the light-emitting portion onto the back wafer, and a second bonding layer configured to bond another light-emitting portion onto the light-emitting portion in a state in which the light-emitting portion is bonded onto the back wafer through the first bonding layer, and a short path is formed in at least one light-emitting portion of the plurality of light-emitting portions so that a current flows into the light-emitting portion in which the short path is not formed, and each of the plurality of LED stacks emits only light having a specific color. According to the present invention, high light transmittance, excellent electrical conductivity, and chemical and thermal stability can be secured through bonding between a transparent conductive material and a transparent insulating material, and at the same time, there is an effect of improving bonding reliability between light-emitting portions.

### CROSS-REFERENCE TO RELATED APPLICATION

This application claims priority to and the benefit of Korean Patent Application No. 10-2025-0004711, filed on Jan. 13, 2025, Korean Patent Application No. 10-2025-0096891, filed on Jul. 17, 2025, and Korean Patent Application No. 10-2025-0149765, filed on Oct. 16, 2025, the disclosure of which is incorporated herein by reference in its entirety.

### BACKGROUND

### 1. Field of the Invention

The present invention relates to a vertically stacked microdisplay panel and a method of manufacturing the same, and more particularly, to a light-emitting diode-on-silicon (LEDOS) microdisplay panel and a method of manufacturing the same, to which an engineering monolithic epitaxy wafer method using a ceramic material is applied during a process of bonding a front wafer and a back wafer, thereby eliminating a need for a process of arranging light-emitting diode (LED) stacks and complementary metal oxide semiconductor (CMOS) electrode pads.

### 2. Discussion of Related Art

The types of implementations of the metaverse, which have recently been attracting attention, are classified into four types including virtual reality (VR)), augmented reality (AR), mixed reality (MR), and extended reality (XR). Among these, it is expected that a metaverse ecosystem will be developed based on XR, which is a reality in which VR, AR and MR are combined, in the future. In order to effectively implement XR, there is a need for devices (for example, smart glasses or head-mounted displays) that include microdisplays with a diagonal length of less than 1 inch as a core component, along with software for next-generation computing platforms that can provide innovative user experience. In particular, the development of high-performance microdisplay panel technologies is absolutely required to provide the greatest immersion, visibility, and convenience to XR users and minimize dizziness.

As shown in FIG. 1, a microdisplay panel 10 according to the related art is a technology in which a Si complementary metal oxide semiconductor (CMOS) semiconductor wafer process is combined with a high-resolution, high-luminance, and ultra-small display process. The microdisplay panel 10 of the related art may have a structure in which a Si CMOS wafer 11 having a size of 4″ or more and a (100) crystal plane and including a plurality of CMOS electrode pads 12 is bonded to a transparent wafer 13 having a size of less than 4″ and including a micro-light-emitting diode (LED) electrode pad 14 and a plurality of micro-LED chips 15, through a conductive attachment portion 16. Meanwhile, the types of microdisplay panels expected to be applied to XR devices include liquid crystal (LC)-based LC-on-Si (LCoS) panels, organic light-emitting diode (OLED)-based OLED-on-Si (OLEDOS) panels, and ultra-small micro-LED-based LED-on-Si (LEDOS) panels, of which a pixel size is less than 5 μm. VR devices to which low-pixel density displays are applied are being developed and mass-produced around LCOS and OLEDOS panels.

However, with the development of metaverse implementation technologies, there is an increasing need for lightweight AR, MR, and XR devices to which high-pixel density microdisplay panels are applied. In order to satisfy this need, there is an urgent need to develop an LEDOS technology which adopts a micro-LED pixel light source including red, green, and blue subpixels each having a size of less than 5 μm and is considered to be an ideal solution in theory based on the superior properties of inorganic materials, but a microdisplay panel platform therefor has not yet been established.

LEDOS based on ultra-small micro-LEDs with a pixel size of less than 5 μm has advantages of an excellent power-to-performance ratio and a short response speed when applied to XR devices and has advantages in that inorganic materials are used to have a long lifetime, power is efficiently used to reduce heat generation, and a battery is usable for the long-term. In particular, since XR devices have a very short distance between a display and the eyes, even a little time delay in image conversion may easily cause discomfort such as dizziness. Therefore, LEDOS which has a nanosecond response speed is considered to be the most suitable for XR devices as compared to LCOS and OLEDOS which have a microsecond response speed.

Furthermore, it is evaluated that the biggest reason why LEDOS is attracting attention in AR, MR, and XR devices unlike in VR is due to luminance and luminous efficiency. Due to the characteristics of smart glasses that can be worn regardless of location, high brightness is an essential condition for normal operation even in outdoor environments such as sunlight, and in theory, micro-LEDs support a luminance of tens to millions of nits, and while OLEDs are organic, micro-LEDs are inorganic and thus also have an advantage of high luminous efficiency.

However, despite the above-described advantages, the biggest reason why LEDOS based on ultra-small micro-LEDs with a pixel size of less than 5 μm is not used for a major component of XR devices is that LEDOS is difficult to mass-produce. That is, in LEDOS, since millions of ultra-small micro-LEDs should be fixed onto a Si CMOS wafer, the process difficulty is high and the yield is very low, which leads to an increase in manufacturing costs to generate a high component price. Thus, the high component price is reflected in the final consumer price, and the LEDOS is supplied as a high-priced XR device, which makes it difficult to meet market demand.

Meanwhile, referring to FIG. 2, up to now, LEDOS using a Group III-V compound (GaN, GaP, or the like) micro-LED light source has been developed through traditional approaches such as \textcircled{1} monolithic integration of a wafer (or a unit die) consisting of micro-LED arrays on a CMOS wafer or \textcircled{2} hybridization between wafers (or unit dies) on a blue, green, or red light source wafer (or a unit die) on which CMOS wafers or micro-LED arrays are manufactured.

Up to now, one of the biggest obstacles to the development of LEDOS using blue, green, and red micro-LED light sources consisting of Group III-V compounds is that it is not easy to secure a solution for pixels having a size of less than 5 μm. Recently, 5 μm level pixels have been successfully demonstrated using monolithic integration technologies, and some product demonstrations developed based on hybridization technologies have been manufactured using sapphire flip chips to achieve 10 μm level pixels. In addition, it has been demonstrated that it is possible to reduce pixels on a 5 μm level in the same way using micro tube interconnections in hybridization technologies. However, both monolithic integration and hybridization technologies are impractical solutions with significant difficulties in mass production in terms of quality and yield and have a problem that mass production is difficult.

The above-described monolithic integration technology and hybrid technology have the common characteristics in which a front plane wafer consisting of Group III-V compound micro-LED arrays and a Si CMOS back plane wafer consisting of a number of integrated circuit (IC) electrode pad arrays are each separately designed and manufactured and then assembled. Since micro-LED arrays manufactured at a unit die-level or wafer-level on Si CMOS wafers should be arranged ultra-finely in any way, in this case, the arrangement is limited by the precision of a process-related device, which seriously affects pixels and pixel to pixel distance (pitch) limitations and causes a problem that mass production is also difficult. Accordingly, in order to manufacture LEDOS to which blue, green, and red micro-LED light sources, which have high resolution and high luminance, are driven at a high speed, include pixels with a size of less than 5 μm, and have a pitch of less than 3 μm, are applied, there is a need for new alternative solutions that can solve the above-described ultra-fine arrangement constraints.

Accordingly, although several impressive product demonstrations, which include 6 μm pixels using engineering monolithic epitaxy wafers manufactured through a low-temperature metal bonding process between a Si CMOS wafer and a micro-LED array wafer, have been recently released, mass production is considered impossible due to low quality and yield issues caused by low-temperature metal bonding and the use of wafers with a small diameter of 6 inches or less. Above all, when ultra-fine pixels with a size of less than 3 μm for microdisplays are manufactured using conventional engineering monolithic epitaxy wafers through metal bonding, a patterning etching process faces even greater difficulties.

As another example, a novel engineering monolithic epitaxy wafer approach, which has made significant progress in solving a problem of a limitation on the brightness and resolution of LEDOS with Group III-V compound micro-LED light sources and simultaneously is capable of providing mass production and low-cost manufacturing solutions through the use of 12-inch diameter Si CMOS wafers, has been proposed.

Referring to FIG. 3, specifically, a process using an engineering monolithic epitaxy wafer is performed through the following four operations. \textcircled{1} First, by using an LED epitaxy wafer, LED epitaxies cut to a predetermined size (for example, 4 mm×6 mm) are arranged and bonded onto a 12-inch large diameter Si blanket wafer at a unit die level. Afterwards, a growth wafer and a buffer layer of the LED epitaxy are removed to then perform planarization and leave only an LED active layer with a predetermined thickness (for example, about 5 μm) on the large diameter Si blank wafer, and then an LED fab process is completed in the form of pixel chips. \textcircled{2} Next, the Si blanket wafer with the completed pixel chips is bonded to a 12-inch CMOS IC Si wafer at a wafer level through multi-layer metal bonding. \textcircled{3} Afterward, the Si blanket wafer is removed. \textcircled{4} Next, residual processes are finally performed on a micro-LED array functioning as pixels on the CMOS IC silicon wafer.

However, in operation \textcircled{1}, when LED epitaxy unit dies are bonded onto the Si blank wafer, there is a limitation in that the dies should be bonded by necessarily arranging positions on a Si CMOS IC wafer with the same size, and in operation \textcircled{2}, during bonding with multilayer metals including low-melting-point metals (Sn and In), there is a problem that a discharge phenomenon in which low-melting-point metal components overflow relatively easily occurs to cause short circuit defects in which micro-LED subpixel arrays in a panel are electrically connected to each other or are connected to neighboring CMOS IC electrode pad arrays adjacent thereto. Furthermore, in operation \textcircled{2}, there is a problem that, due to the optically non-transparent characteristics of the Si blanket wafer and a multilayer metal bonding layer, ultra-fine arrangement wafer bonding between the Si blanket wafer (that is, a front plane wafer) and the CMOS IC Si wafer is difficult, which causes defects. Here, ultra-fine arrangement refers to a process of matching and arranging micro-LED arrays, which consist of hundreds of thousands to tens of millions of ultra-small pixel chips provided on a Si blanket wafer, with CMOS IC electrode pad arrays provided on a CMOS IC Si wafer on a one-to-one basis.

That is, the engineering monolithic epitaxy wafer approach presented in the above-described technologies is evaluated as a solution that is a step closer to implementing LEDOS based on ultra-small micro-LEDs with a pixel size of less than 5 μm. However, there are quality and yield issues due to the use of metals (low temperature, multilayer) in wafer bonding, it is very difficult to manufacture high-resolution microdisplays including ultra-fine pixels with a size of less than 3 μm, and there are also problems according to some arrangement processes. Thus, a new alternative is needed for this.

In addition, in vertically stacked tandem structures of microdisplays that adopt conventional micro-LED pixel light sources, color filters are still applied to implement full color, and thus there are disadvantages in terms of color quality, process complexity, and productivity.

Meanwhile, when only a transparent conductive oxide (TCO) such as indium tin oxide (ITO) is used for a bonding layer in a process of manufacturing a vertically stacked microdisplay panel, there is a problem in degradation of bonding reliability between light-emitting portions, which causes a problem that the overall quality and manufacturing yield of the microdisplay panel are reduced.

### Related Art Documents

### Patent Documents

(Patent Document 0001) Korean Laid-Open Patent No. 10-2018-0009116

### SUMMARY OF THE INVENTION

The present invention is directed to providing a light-emitting diode-on-silicon (LEDOS) microdisplay panel and a method of manufacturing the same, to which an engineering monolithic epitaxy wafer method using a ceramic material is applied during a process of bonding a front wafer and a back wafer, thereby eliminating a need for a process of arranging light-emitting diode (LED) stacks and complementary metal oxide semiconductor (CMOS) electrode pads.

The present invention is also directed to providing an LEDOS vertically stacked microdisplay panel and a method of manufacturing the same, in which high light transmittance, excellent electrical conductivity, and chemical and thermal stability can be secured through bonding between a transparent conductive material and a transparent insulating material, and at the same time, surface flatness of a bonding layer can be improved, and bonding reliability between light-emitting portions can be improved.

According to an aspect of the present invention, there is provided a vertically stacked microdisplay panel including a back wafer having an upper surface on which a plurality of CMOS electrode pads are arranged, a plurality of light-emitting diode LED stacks, each of which includes a plurality of light-emitting portions vertically stacked through a bonding layer and is arranged on one of the plurality of CMOS electrode pads, and a common electrode formed on the plurality of LED stacks, wherein the bonding layer includes a first bonding layer configured to bond the light-emitting portion onto the back wafer, and a second bonding layer configured to bond another light-emitting portion onto the light-emitting portion in a state in which the light-emitting portion is bonded onto the back wafer through the first bonding layer, and a short path is formed in at least one light-emitting portion of the plurality of light-emitting portions so that a current flows into the light-emitting portion in which the short path is not formed, and each of the plurality of LED stacks emits only light having a specific color.

The first bonding layer may be formed of a metallic material.

The first bonding layer may be formed of a transparent electrically conductive material.

The second bonding layer may be formed of a transparent electrically insulating material.

A functional layer in ohmic contact with the light-emitting portion may be formed on one surface of the light-emitting portion, and the second bonding layer may be bonded to the functional layer to bond the another light-emitting portion onto the light-emitting portion.

The short path may be formed to pass through the first bonding layer.

According to another aspect of the present invention, there is provided a method of manufacturing a vertically stacked microdisplay panel, the method including a preparation operation of preparing a front wafer including a support wafer and light-emitting portions, and a back wafer having an upper surface on which a plurality of complementary metal oxide semiconductor CMOS electrode pads are arranged, a bonding operation of bonding the plurality of light-emitting portions onto the back wafer by repeating a process of bonding the front wafer onto the back wafer through a bonding layer and then removing the support wafer, an etching operation of etching and dividing the plurality of stacked light-emitting portions and the bonding layer into preset units and arranging a plurality of LED stacks on the plurality of CMOS electrode pads, and a forming operation of forming a common electrode on the plurality of LED stacks, wherein the bonding layer includes a first bonding layer configured to bond the light-emitting portion onto the back wafer, and a second bonding layer configured to bond another light-emitting portion onto the light-emitting portion in a state in which the light-emitting portion is bonded onto the back wafer through the first bonding layer, and a short path is formed in at least one light-emitting portion of the plurality of light-emitting portions so that a current flows into the light-emitting portion in which the short path is not formed, and each of the plurality of LED stacks emits only light having a specific color.

The first bonding layer may be formed of a metallic material.

The first bonding layer may be formed of a transparent electrically conductive material.

The second bonding layer may be formed of a transparent electrically insulating material.

A functional layer in ohmic contact with the light-emitting portion may be formed on one surface of the light-emitting portion, and the second bonding layer may be bonded to the functional layer to bond the other light-emitting portion onto the light-emitting portion.

The short path may be formed to pass through the first bonding layer.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 illustrates a structure of a microdisplay panel according to a related art;

FIG. 2 illustrates a light-emitting diode-on-silicon (LEDOS) development approach according to a related art;

FIG. 3 illustrates an approach using an engineering monolithic epitaxy wafer according to a related art;

FIG. 4 illustrates a process of preparing a front wafer with a p-side up form in a method of manufacturing a vertically stacked microdisplay panel according to one embodiment of the present invention;

FIG. 5 illustrates a process of preparing a front wafer with an n-side up form in the method of manufacturing a vertically stacked microdisplay panel according to one embodiment of the present invention;

FIG. 6 illustrates a process of preparing a back wafer in the method of manufacturing a vertically stacked microdisplay panel according to one embodiment of the present invention;

FIG. 7 is a flowchart of the method of manufacturing a vertically stacked microdisplay panel according to one embodiment of the present invention;

FIGS. 8 to 10 illustrate a process of manufacturing a vertically stacked microdisplay panel according to the method of manufacturing a vertically stacked microdisplay panel according to one embodiment of the present invention;

FIG. 11 illustrates a vertically stacked microdisplay panel manufactured according to the method of manufacturing a vertically stacked microdisplay panel according to one embodiment of the present invention;

FIGS. 12 to 14 illustrate a case in which a first bonding layer is formed of a different material during a process of manufacturing a vertically stacked microdisplay panel according to the method of manufacturing a vertically stacked microdisplay panel according to one embodiment of the present invention; and

FIG. 15 illustrates a case in which the first bonding layer is formed of a different material in the vertically stacked microdisplay panel manufactured according to the method of manufacturing a vertically stacked microdisplay panel according to one embodiment of the present invention.

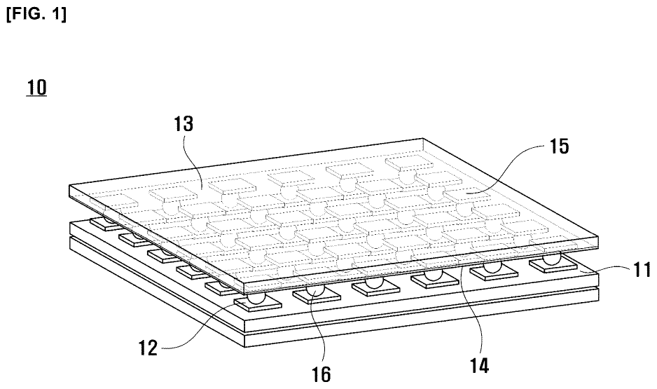

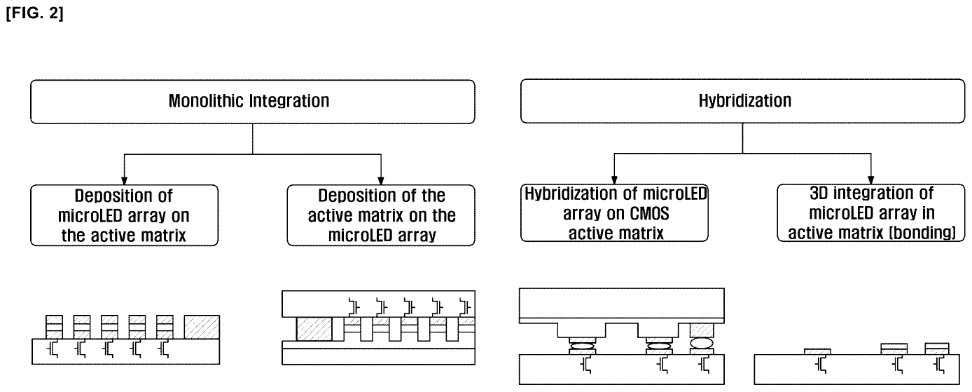

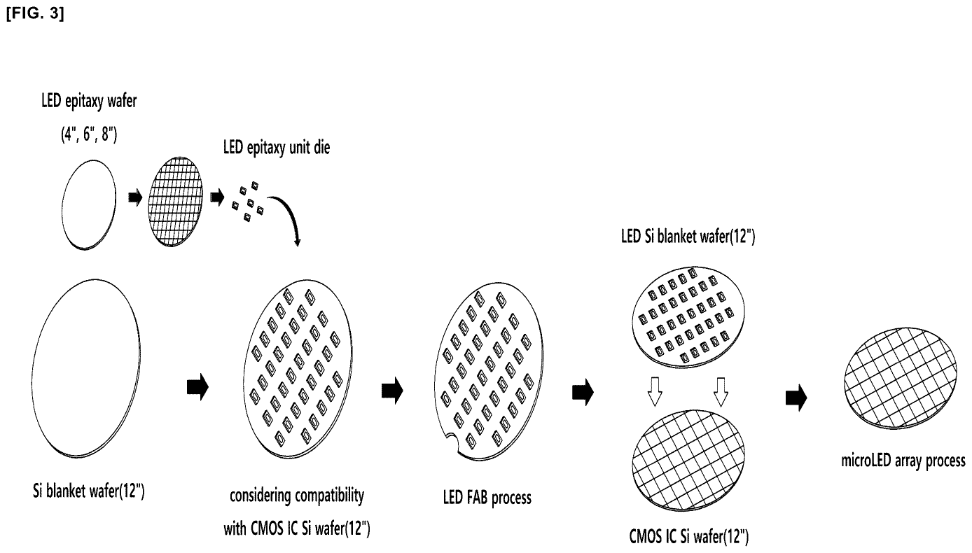

### DETAILED DESCRIPTION OF EXEMPLARY EMBODIMENTS

Hereinafter, some embodiments of the present disclosure will be described in detail through exemplary drawings. When assigning reference numerals to components of each of the drawings, it should be noted that identical components are denoted by the same reference numerals as much as possible even when they are shown on different drawings.

In addition, when describing embodiments of the present disclosure, when a detailed description of a related known configuration or function is determined to hinder understanding of the embodiment of the present disclosure, the detailed description is omitted.

In addition, when describing components of embodiments of the present disclosure, terms such as first, second, A, B, (a), (b), and the like may be used. These terms are only intended to distinguish the components from other components, and the nature, order, or sequence of the components are not limited by the terms. These terms are only for the purpose of distinguishing one component from another component, and the nature, sequence, order, or the like of the corresponding components is not limited by these terms.

Hereinafter, a method S100 of manufacturing a vertically stacked microdisplay panel according to one embodiment of the present invention will be described in detail with reference to the accompanying drawings.

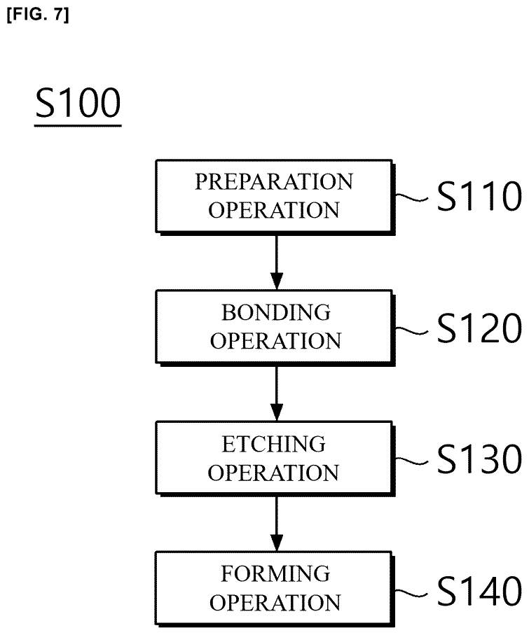

FIG. 7 is a flowchart of the method of manufacturing a vertically stacked microdisplay panel according to one embodiment of the present invention.

Referring to FIG. 7, the method S100 of manufacturing a vertically stacked microdisplay panel according to one embodiment of the present invention includes a preparation operation S110, a bonding operation S120, an etching operation S130, and a forming operation S140.

The preparation operation S110 is an operation of preparing a plurality of front wafers 110 and a back wafer 140.

Here, the front wafer 110 may be a front plane wafer and include a first front wafer including a first light-emitting portion 121 that emits light having a first color, a second front wafer including a second light-emitting portion 122 that emits light having a second color different from the first color, and a third front wafer including a third light-emitting portion 123 that emits light having a third color different from the first and second colors. Meanwhile, the first color, the second color, and the third color may be, for example, a red color, a green color, and a blue color, respectively, but are not limited thereto, and may include various other colors.

The front wafer 110 may include a support wafer S and a light-emitting portion 120 disposed on the support wafer S.

The light-emitting portion 120 may generate light and emit blue, green, or red light. In the present invention, when the light-emitting portion 120 emits blue or green light, binary, ternary, or quaternary compounds such as InN, InGaN, GaN, AlGaN, AlN, and AlGaInN, which are Group III (Al, Ga, and In) nitride semiconductors among Group III-V compound semiconductors, may be disposed at an appropriate position and order on an initial growth wafer G and epitaxially grown.

In particular, in order to emit blue light or green light, a high-quality Group III nitride semiconductor such as InGaN having a high In composition should be preferentially formed on a Group III nitride semiconductor consisting of GaN, AlGaN, AlN, or AlGaInN, but the present invention is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are Group III (Al, Ga, and In) phosphide semiconductors among Group III-V compound semiconductors, may be disposed at an appropriate position and order on the initial growth wafer G and epitaxially grown. In addition, in recent years, in order to further improve the development of equipment and process technologies and the value of display panel products, when red light is emitted, rather than a Group III phosphide semiconductor, a high-quality Group III nitride semiconductor such as InGaN with a high In composition of 30% or more may be preferentially formed on a Group III nitride semiconductor consisting of GaN, AlGaN, AlN, and AlGaInN.

In particular, in order to emit red light, a high-quality Group III phosphide semiconductor having a high In composition such as InGaP should be preferentially formed on a Group III phosphide semiconductor consisting of GaP, AlInP, AlGaP, AlP, AlGaInP, but the present invention is not limited thereto. Hereinafter, a Group III nitride semiconductor will be mainly described.

Each light-emitting portion 120 may include, more specifically, a first semiconductor region 1201 (for example, a p-type semiconductor region), an active region 1203 (for example, a multi-quantum well (MQW)), and a second semiconductor region 1202 (for example, an n-type semiconductor region). The light-emitting portion 120 may have a structure in which the second semiconductor region 1202, the active region 1203, and the first semiconductor region 1201 are sequentially and epitaxially grown on the growth wafer G and may typically have an overall thickness of about 5.0 μm to about 8.0 μm by ultimately including a plurality of layers of Group III nitrides, but the present invention is not limited thereto.

Each of the first semiconductor region 1201, the active region 1203, and the second semiconductor region 1202 may be provided as a single layer or multiple layers, and although not shown, before the light-emitting portion 120 is epitaxially grown on the growth wafer G, necessary layers such as a buffer layer may be added to improve the quality of the epitaxially grown light-emitting portion 120. For example, the buffer layer may typically have a thickness of about 4.0 μm by including a compliant layer (CL) consisting of a nucleation layer (NL) and an un-doped semiconductor region to relieve stress and improve thin film quality. In addition, when the growth wafer G is removed using a laser lift-off (LLO) technique, a sacrificial layer (SL) may be provided between the NL and the un-doped semiconductor region, and a seed layer may serve as the SL.

The second semiconductor region 1202 has second conductivity (n-type) and is formed on the growth wafer G. This second semiconductor region 1202 may have a thickness of 2.0 μm to 3.5 μm.

The active region 1203 generates light using the recombination between electrons and holes and is formed on the second semiconductor region 1202. The active region 1203 may be provided as a plurality of layers to have a thickness of several tens nm.

The first semiconductor region 1201 has first conductivity (p-type) and is formed on the active region 1203. The first semiconductor region 1201 may be provided as a plurality of layers to have a thickness of several tens of nm to several μm, and an upper surface thereof may have gallium polarity (Ga-polarity).

That is, the active region 1203 may be interposed between the first semiconductor region 1201 and the second semiconductor region 1202 so that holes of the first semiconductor region 1201, which is a p-type semiconductor region, may recombine with electrons of the second semiconductor region 12012, which is an n-type semiconductor region, in the active region 1203 to generate light.

In addition, a functional layer 124 may be formed on an upper surface of the light-emitting portion 120.

Specifically, the functional layer 124 may be formed in contact with the light-emitting portion 120 to be in ohmic contact therewith and may be formed as a single layer or multiple layers.

In this case, when the functional layer 124 is formed as a single layer, the functional layer 124 may only include an ohmic contact layer. On the other hand, when the functional layer 124 is formed as multiple layers, the functional layer 124 may include an ohmic contact layer and a highly transparent bonding layer.

Specifically, when the functional layer 124 is formed as a single layer, the ohmic contact layer should have excellent ohmic properties, transparency, and bonding properties. On the other hand, when the functional layer 124 is formed as multiple layers, it is important for the ohmic contact layer to secure excellent ohmic properties and a certain level of transparency, and the highly transparent bonding layer performs a bonding function by being formed of a transparent material (for example, indium tin oxide (ITO) or indium zinc oxide (IZO) that has conductivity even though ohmic properties thereof are relatively low.

The material of the functional layer 124 may include NiO, PtO, PdO, AgO₂, Au, Rh₂O₃, RuO₂, In₂O₃, SnO₂, ZnO, ITO, IZO, indium gallium zinc oxide (IGZO), zinc indium tin oxide (ZITO), indium molybdenum oxide (IMoO), indium titanium oxide (ITiO), indium titanium oxynitride (ITON), indium zinc oxynitride (IZON), NiO—Au, and/or NiO—Ag, among which ITO, IZO, NiO—Au, or NiO—Ag may be preferentially selected, but the present invention is not limited thereto.

The support wafer S may support the light-emitting portion 120 positioned thereon. When the initial growth wafer G is not removed, the growth wafer G may be the support wafer S, or the support wafer S may be a separate bonded wafer to remove the initial growth wafer G.

Meanwhile, in the present invention, the front wafer 110 may be manufactured and prepared in a p-side up form or an n-side up form.

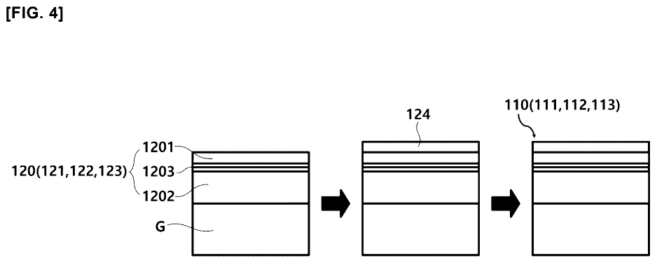

FIG. 4 illustrates a process of preparing a front wafer with a p-side up form in the method of manufacturing a vertically stacked microdisplay panel according to one embodiment of the present invention.

Referring to FIG. 4, a process of manufacturing and preparing the front wafer 110 in a p-side up form is as follows.

In the case of blue light or green light, the second semiconductor region 1202, the active region 1203, and the first semiconductor region 1201 are sequentially and epitaxially grown on a sapphire (α-phase Al2O3) growth wafer G (in the case of red light, a GaAs growth wafer G or the like), and then a p-type functional layer 124 which is transparent and conductive is formed on an upper surface of the first semiconductor region 1201, thereby preparing the front wafer 110 with a p-side up form. In this case, the growth wafer G may serve as the support wafer S, and the front wafer 110 may have a structure in which the support wafer S, the second semiconductor region 1202, the active region 1203, the first semiconductor region 1201, and the functional layer 124 are sequentially stacked.

Meanwhile, in the case of blue light and green light, the light-emitting portion 120 that emits blue light or green light may be formed on Si having a (111) crystal plane instead of the sapphire (α-phase Al2O3) growth wafer G, and in this case, a Si growth wafer G may be separated and removed through mechanical polishing (MP) or a chemical etching technique (chemical lift-off (CLO)).

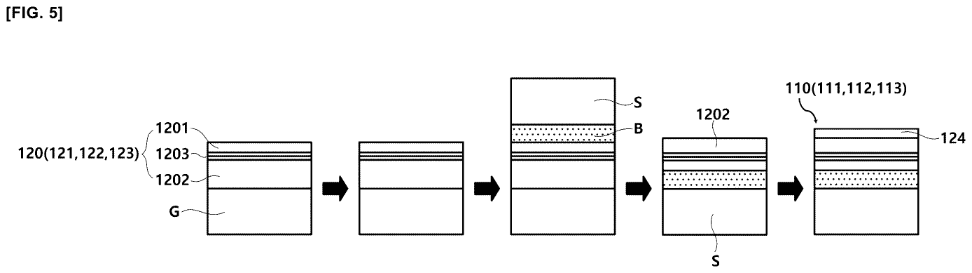

FIG. 5 illustrates a process of preparing a front wafer with an n-side up form in the method of manufacturing a vertically stacked microdisplay panel according to one embodiment of the present invention.

As shown in FIG. 5, a process of manufacturing and preparing the front wafer 110 in an n-side up form is as follows.

In the case of blue light or green light, the second semiconductor region 1202, the active region 1203, and the first semiconductor region 1201 are sequentially and epitaxially grown on a sapphire (α-phase Al2O3) growth wafer G (in the case of red light, a GaAs growth wafer G or the like), and then the support wafer S is bonded to an upper surface through a temporary bonding layer B. Afterwards, the growth wafer G is separated from the light-emitting portion 120 using an LLO or CLO technique, the second semiconductor region 1202 is etched to reduce a thickness of the second semiconductor region 1202, and then an n-type functional layer 124 which is transparent and conductive is formed on a surface of the second semiconductor region 1202 of which the thickness has been reduced, thereby preparing the front wafer 110 with an n-side up form. In this case, the support wafer S may be formed of a Si material having a (111), (110), or (100) crystal plane, but the present invention is not limited thereto. The front wafer may have a structure in which the support wafer S, the temporary bonding layer B, the first semiconductor region 1201, the active region 1203, the second semiconductor region 1202, and the functional layer 124 are sequentially stacked.

Furthermore, in the present invention, materials of the growth wafer G and/or support wafer S may each be sapphire or silicon (Si), but the selection of the material may be determined according to a wafer bonding method.

For example, when bonding is performed at room temperature through a surface activation process (surface activated bonding), wafers formed of different materials such as sapphire and silicon (Si) may each be selected irrespective of thermal expansion coefficients. However, when wafer bonding between the growth wafer G, the support wafer S, and the back wafer 140 is performed at a temperature of 50 °C or higher, or when annealing is performed at a temperature of 50 °C or higher without removing a wafer at one side in a state in which bonding between wafers have been performed, wafers formed of the same material should be selected.

Meanwhile, in a process of manufacturing the front wafer 110 described above, before the functional layer 124 is formed on a surface of the first semiconductor region 1201 or the second semiconductor region 1202, when the surface of the first semiconductor region 1201 is exposed, each surface may be polished and smoothly planarized through MP or chemical-mechanical polishing (CMP) to have a smooth surface.

In addition, a surface of the functional layer 124 formed on the front wafer 110 may also be polished and smoothly planarized through MP or CMP.

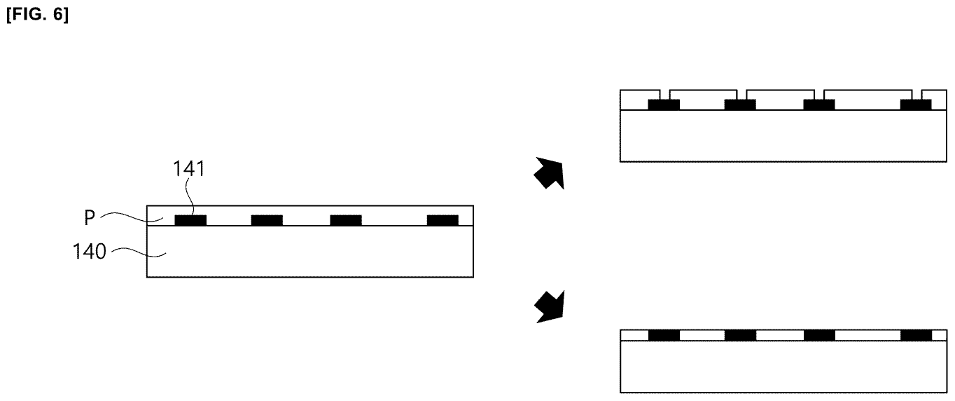

FIG. 6 illustrates a process of preparing a back wafer in the method of manufacturing a vertically stacked microdisplay panel according to one embodiment of the present invention.

Referring to FIG. 6, the back wafer 140 is a complementary metal oxide semiconductor (CMOS) panel in which, as an active driving integrated circuit (IC) driven through an active matrix (AM) method, a plurality of CMOS electrode pads 141 are arrayed on an upper surface thereof. The plurality of CMOS electrode pads 141 may include individual CMOS electrode pads 141 that function as individual electrodes and common CMOS electrode pads 141 that function as a common electrode. A passivation layer P may be formed on the back wafer 140 such that upper surfaces of the plurality of CMOS electrode pads 141 are not exposed.

In this case, openings may be formed in the passivation layer P on the CMOS electrode pads 141 to expose the surface of the CMOS electrode pad 141, or the entire passivation layer P may be etched to have the same height as the CMOS electrode pads 141 to expose the surface of the CMOS electrode pad 141 to the outside.

Furthermore, the back wafer 140 may be provided as a Si wafer having a (100) crystal plane and may be provided as an 8-inch or 12-inch Si wafer according to a standard CMOS IC process. However, considering that a typical light-emitting diode (LED) wafer (front wafer 110) for bonding has a size of 4 inches or 6 inches, the size of the back wafer 140 is not particularly limited.

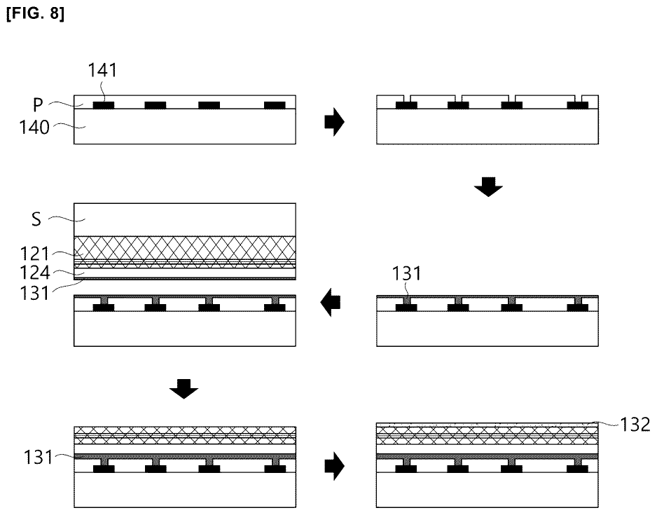

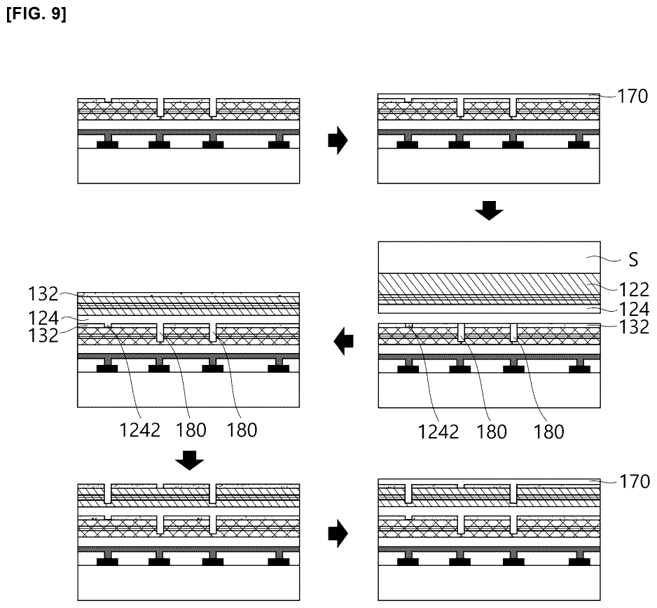

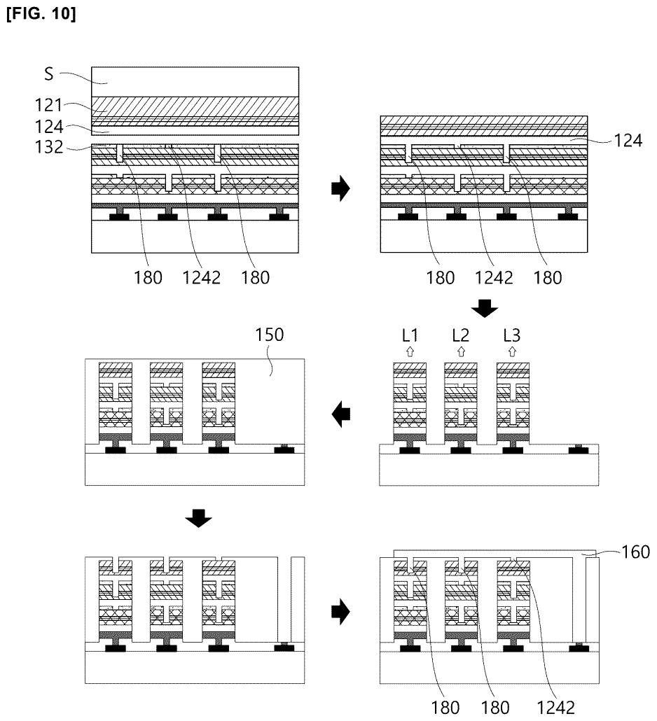

FIGS. 8 to 10 illustrate a process of manufacturing a vertically stacked microdisplay panel according to the method of manufacturing a vertically stacked microdisplay panel according to one embodiment of the present invention.

A vertically stacked microdisplay panel 100 of the present invention may be manufactured using the front wafer 110 with a p-side up form or an n-side up form, and a manufacturing process using the front wafer 110 with a p-side up form will be described below with reference to FIGS. 8 to 10.

The bonding operation S120 is an operation of bonding a plurality of light-emitting portions 120 onto the back wafer 140 and vertically stacking the light-emitting portions 120 by repeating a process of bonding the front wafer 110 onto the back wafer 140 through a bonding layer 130 and then removing the support wafer S.

During a process of manufacturing the vertically stacked microdisplay panel 100, when only a transparent conductive oxide (TCO) such as ITO is used for the bonding layer 130 between the light-emitting portions, there is a problem in degradation of bonding reliability between the light-emitting portions, which causes a problem that the overall quality and manufacturing yield of a microdisplay panel are reduced.

Accordingly, in the present invention, an optically transparent electrically insulating material is additionally introduced during bonding between light-emitting portions, thereby securing high light transmittance, excellent electrical conductivity, and chemical and thermal stability through bonding between a transparent conductive material and a transparent insulating material, and at the same time improving the surface flatness of a bonding layer and improving bonding reliability between the light-emitting portions.

In this case, the bonding layer includes a first bonding layer 131 that bonds the light-emitting portion 120 onto the back wafer 140, and a second bonding layer 132 that bonds another light-emitting portion 120 onto the light-emitting portion 120 in a state in which the light-emitting portion 120 is bonded onto the back wafer 140 through the first bonding layer 131.

More specifically, the bonding operation S120 includes a first bonding operation and a second bonding operation.

The first bonding operation is an operation of bonding the front wafer 110 onto the back wafer 140 through the first bonding layer 131 and then removing the support wafer S to bond the light-emitting portion 120 onto the back wafer 140.

Specifically, in the first bonding operation, the first bonding layer 131 formed of a metallic material is first formed on the front wafer 110, and the first bonding layer 131 is also formed on the back wafer 140, in which the CMOS electrode pad 141 is exposed to the outside, to be electrically connected to the CMOS electrode pad 141. Then, the first bonding layer 131 of the front wafer 110 and the first bonding layer 131 of the back wafer 140 are bonded to each other to bond the front wafer 110 onto the back wafer 140.

Here, a metal bonding method may include eutectic bonding, diffusion bonding, or direct bonding, but the present invention is not limited thereto.

In addition, the first bonding layer 131 that bonds the front wafer onto the back wafer may be formed as a single layer or multiple layers, and when the first bonding layer 131 is formed as multiple layers, the first bonding layer 131 may include a high-reflectivity layer, a diffusion prevention layer, and a metal bonding reinforcement layer.

A material of the first bonding layer 131 may include Ag, AgCu, AgPd, AgCuPd, a Ag alloy, Au, Au alloy, Rh, a Rh alloy, Al, or an Al alloy. When the first bonding layer 131 is formed as multiple layers, the high-reflectivity layer may include Ag, Al, Rh, Au, Pt, Ir, or Cu, the diffusion prevention layer may include W, Pd, Cu, Mo, Ta, TiN, or CrN, and the metal bonding reinforcement layer may include Cr, Ti, Ni, Zr, V, Co, Mn, or Nb, but the present invention is not limited thereto.

After the front wafer 110 is bonded to the back wafer 140, the support wafer S of the front wafer 110 is removed through LLO or CLO, thereby exposing a surface of the light-emitting portion 120 on which the functional layer 124 is not formed.

For example, when the front wafer 110 with a p-side up form is used, in the first bonding operation, the first bonding layer 131 formed at an uppermost portion of a first front wafer 111 is bonded to the first bonding layer 131 formed on the back wafer 140, and then the support wafer S is removed, thereby stacking the first light-emitting portion 121, which emits light having the first color on the back wafer 140, and forming an n-side up structure in which the first bonding layer 131, the p-type functional layer 124, the first semiconductor region 1201, the active region 1203, and the second semiconductor region 1202 are sequentially stacked on the back wafer 140. In this case, of course, the exposed second semiconductor region 1202 may be etched to reduce a thickness of the second semiconductor region 1202.

Thereafter, in the first bonding operation, the second bonding layer 132 is formed on the surface of the second semiconductor region 1202 of the first light-emitting portion 121. Here, the second bonding layer 132 may be formed of a transparent electrically insulating material, and may be formed of, for example, SiO2, SiNx, AlN, or Al₂O₃, but the present invention is not limited thereto.

Thereafter, in the first bonding operation, a through-hole is formed in portions of the second bonding layer 132 and the first light-emitting portion 121, and then the through-hole is filled to form a short layer 170.

Specifically, in the first bonding operation, a through-hole passing through the second bonding layer 132 and the active region 1203 of the first light-emitting portion 121 is formed in an area in which a second LED stack L2 and a third LED stack L3 are to be formed. In the first bonding operation, a through-hole is formed in the second bonding layer 132 in an area in which a first LED stack L1 is to be formed, thereby exposing a surface of the second semiconductor region 1202 of the first light-emitting portion 121.

Thereafter, in the first bonding operation, the through-holes are filled to form the short layer 170 covering the second bonding layer 132.

Here, the through-hole may be filled through a direct self-alignment method or a liquid coating method such as a sol-gel method, thereby forming the short layer 170, but the present invention is not limited thereto.

Meanwhile, the short layer 170 is preferably formed of an optically transparent and electrically conductive material, and the material may include In₂O₃, SnO₂, ZnO, IZO, ITO, IGZO, or the like, but the present invention is not limited thereto.

In addition, the short layer 170 may be formed of a metallic material, and the material may include Ag, Al, Rh, Cu, Au, or the like. Furthermore, a stack structure in which a thin adhesion-enhancing material such as Ti, Ni, Cr, or Pt is stacked to a thickness of several nm or less may be employed, and the short layer may be formed of an alloy such as AgCu or AgNi, but the present invention is not limited thereto.

Thereafter, in the first bonding operation, the short layer 170 is etched through MP or CMP to expose a surface of the second bonding layer 132 therebelow. Accordingly, a short path 180 is formed in an area in which the second LED stack L2 and the third LED stack L3 are to be formed, and an n-type ohmic contact electrode 1242 is formed in an area in which the first LED stack L1 is to be formed.

The second bonding operation is an operation of bonding a plurality of other light-emitting portions 120 on the light-emitting portion 120 by repeating a process of bonding the front wafer 110 onto the light-emitting portion 120 through the second bonding layer 132 then removing the support wafer S in a state in which the light-emitting portion 120 is bonded onto the back wafer 140 through the first bonding layer 131.

For example, in the second bonding operation, the p-type functional layer 124 formed at an uppermost portion of a second front wafer 112 with a p-side up form is bonded to the second bonding layer 132 formed on the first light-emitting portion 121 through the first bonding operation, and then the support wafer S is removed, thereby stacking the second light-emitting portion 122 on the back wafer 140 in an n-side up structure that emits light having the second color. In this case, of course, the exposed second semiconductor region 1202 may be etched to reduce the thickness of the second semiconductor region 1202.

Thereafter, in the second bonding operation, after the second bonding layer 132 is formed on the surface of the second semiconductor region 1202 of the second light-emitting portion 122, a through-hole is formed in portions of the second bonding layer 132 and the second light-emitting portion 122, and then the through-hole is filled to form the short layer 170.

Specifically, in the second bonding operation, a through-hole is formed to pass through the second bonding layer 132 and the active region 1203 of the second light-emitting portion 122 in an area in which the first LED stack L1 and the third LED stack L3 are to be formed, and a through-hole is formed in the second bonding layer 132 in an area in which the second LED stack L2 is to be formed, thereby exposing the surface of the second semiconductor region 1202 of the second light-emitting Portion 122.

Thereafter, in the second bonding operation, the through-holes are filled to form a short layer 170 covering the second bonding layer 132, and the short layer 170 is etched through MP or CMP to expose the surface of the second bonding layer 132 therebelow. Accordingly, the short path 180 is formed in an area in which the first LED stack L1 and the third LED stack L3 are to be formed, and the n-type ohmic contact electrode 1242 is formed in an area in which the second LED stack L2 is to be formed.

Next, in the second bonding operation, the p-type functional layer 124 formed at an uppermost portion of a third front wafer 113 with a p-side up form is bonded to the second bonding layer 132 formed on the second light-emitting portion 122, and then the support wafer S is removed, thereby stacking the third light-emitting portion 123 on the back wafer 140 in an n-side up structure that emits light having the third color. In this case, of course, the exposed second semiconductor region 1202 may be etched to reduce the thickness of the second semiconductor region 1202.

Meanwhile, in the above example, an example in which the first light-emitting portion 121, the second light-emitting portion 122, and the third light-emitting portion 123 are sequentially stacked has been described, but the present invention is not limited thereto. A various number of light-emitting portions 120 may be stacked in various orders.

The etching operation S130 is an operation of etching and dividing the plurality of stacked light-emitting portions 120, functional layers 124, first bonding layer 131, and second bonding layers 132 into preset units to arrange a plurality of LED stacks L on the individual CMOS electrode pads 141, thereby eliminating a need for a process of arranging the LED stacks L of the conventional front wafer 110 and the CMOS electrode pads 141 of the back wafer 140.

For example, in the etching operation S130, the light-emitting portions 120, the functional layer 124, the first bonding layer 131, and the second bonding layer 132 are vertically etched until a passivation layer P of the back wafer 140 is exposed, thereby arranging the LED stacks L the individual CMOS electrode pads 141, and also exposing an upper portion of the common CMOS electrode pad 141 to the outside. In this case, the first bonding layer 131 may remain on the common CMOS electrode pad 141 and function as a connection electrode.

Meanwhile, here, the preset unit may refer to a pixel or subpixel unit and may refer to a diameter (width) of the LED stack L. The LED stack L may include the first LED stack L1 for emitting only light having the first color, the second LED stack L2 for emitting only light having the second color, and the third LED stack L3 for emitting only light having the third color.

In this case, since a ceramic material is used rather than a metal, both the second bonding layer 132 and the functional layer 124 of the present invention are easy to etch in a plasma dry process, and there is an advantage in that a problem of re-deposition of etch by-products does not occur.

Afterwards, in the etching operation S130, a mold portion 150 is formed to fill a space between the plurality of LED stacks L, and then a through-hole is formed in portions of the mold portion 150 and the third light-emitting portion 123.

Specifically, in the etching operation S130, a through-hole is formed to pass through the mold portion 150 on each of the first LED stack L1 and the second LED stack L2 and the active region 1203 of the third light-emitting portion 123, and a through-hole is formed in the mold portion 150 on the third LED stack L3, thereby exposing the surface of the second semiconductor region 1202 of the third light-emitting portion 123. Furthermore, in the etching operation S130, a through-hole is formed in the mold portion 150 such that the first bonding layer 131 on the common CMOS electrode pad 141 is exposed to the outside.

The forming operation S140 is an operation of forming a common electrode 160 on the plurality of LED stacks L.

Specifically, in the forming operation S140, the through-holes formed in the etching operation S130 are filled to form the common electrode 160 so that the short path 180 is formed in the first LED stack L1 and the second LED stack L2, and the n-type ohmic contact electrode 1242 is formed in the third LED stack L3.

The common electrode 160 may be formed of a material that is transparent and conductive, similar to the functional layer 124. When the common electrode is a negative electrode, a common electrode material may include In, InGa, Ga, InN, InGaN, GaN, TiN, TiNO, CrN, VN, In2O3, SnO2 , ZnO, ITO, IZO, strontium Titanate (STO), and/or indium gallium zinc oxide (IGZO), and when the common electrode is a positive electrode, the common electrode material may include NiO, PtO, PdO, AgO₂, Au, Rh₂O₃, RuO₂, In₂O₃, SnO₂, ZnO, ITO, IZO, IGZO, ZITO, IMoO, ITiO, ITON, IZON, NiO—Au, and/or NiO—Ag, but the present invention is not limited thereto.

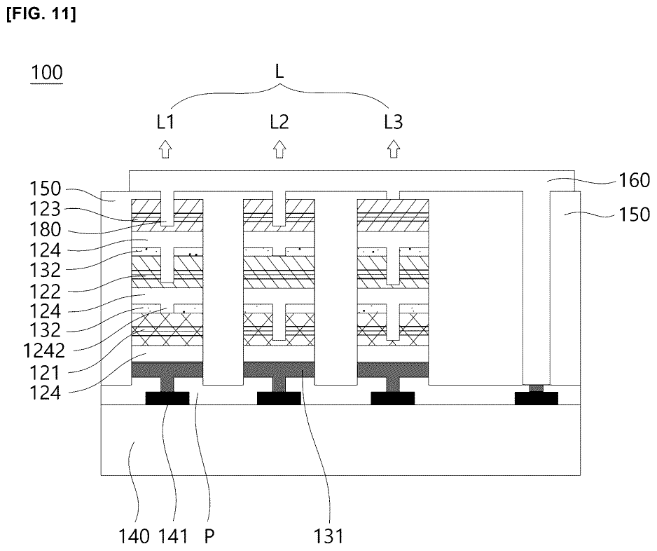

FIG. 11 illustrates the vertically stacked microdisplay panel manufactured according to the method of manufacturing a vertically stacked microdisplay panel according to one embodiment of the present invention.

Referring to FIG. 11, the vertically stacked microdisplay panel 100 manufactured according to the method S100 of manufacturing a vertically stacked microdisplay panel according to one embodiment of the present invention described above includes the back wafer 140 having an upper surface on which the plurality of CMOS electrode pads 141 are arranged, the plurality of LED stacks L which each include the plurality of light-emitting portions 120 vertically stacked through the bonding layer and are arranged on the plurality of CMOS electrode pads 141, and the common electrode 160 formed on the plurality of LED stacks L, wherein the bonding layer includes the first bonding layer 131 that bonds the light-emitting portion 120 onto the back wafer 140, and the second bonding layer 132 that bonds another light-emitting portion 120 onto the light-emitting portion 120 in a state in which the light-emitting portion 120 is bonded onto the back wafer 140 through the first bonding layer 131. Here, the first bonding layer 131 may be formed of a metallic material.

In this case, the functional layer 124 in ohmic contact with the light-emitting portion 120 is formed on one surface of the light-emitting portion 120, and the second bonding layer 132 formed of a transparent electrically insulating material is bonded to the functional layer 124 formed of a transparent electrically conductive material, thereby bonding another light-emitting portion 120 onto the light-emitting portion 120.

In particular, since the short path 180 is formed in at least one light-emitting portion of the plurality of light-emitting portions 120, a current may flow into the light-emitting portion 120 in which the short path 180 is not formed, and thus each of the plurality of LED stacks L of the present invention may emit only light having a specific color.

Specifically, since the short path 180 is formed to pass through the third light-emitting portion 123 and the second light-emitting portion 122, a current may not flow into the third light-emitting portion 123 and the second light-emitting portion 122, and a current may flow only into the first light-emitting portion 121 so that the first LED stack LI of the present invention may emit only light having the first color.

In addition, since the short path 180 is formed to pass through the third light-emitting portion 123 and the first light-emitting portion 121, a current may not flow into the third light-emitting portion 123 and the first light-emitting portion 121, and a current may flow only into the second light-emitting portion 122 so that the second LED stack L2 of the present invention may emitting only light having the second color.

In addition, since the short path 180 is formed to pass through the second light-emitting portion 122 and the first light-emitting portion 121, a current may not flow into the second light-emitting portion 122 and the first light-emitting portion 121, and a current may flow only into the third light-emitting portion 123 so that the third LED stack L3 of the present invention may emit only light having the third color.

That is, since the short path 180 is formed in at least one light-emitting portion 120 of the plurality of stacked light-emitting portions 120, a current flows into the light-emitting portion 120 in which a short path D180 is not formed, and thus each of the plurality of LED stacks L emits only light having a specific color.

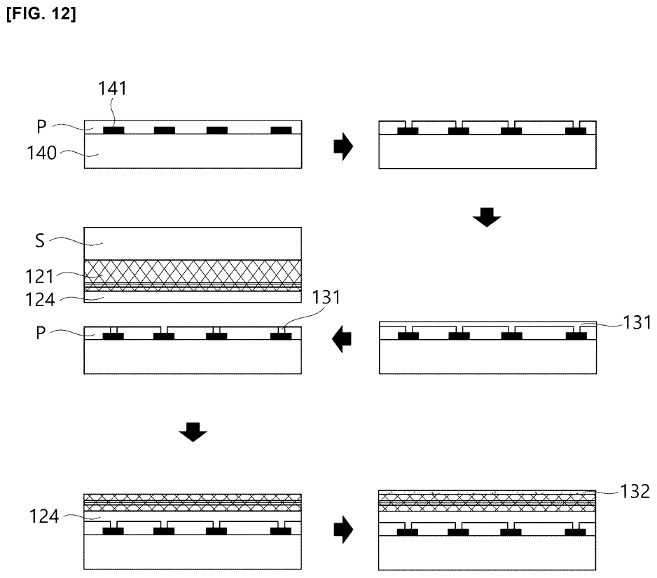

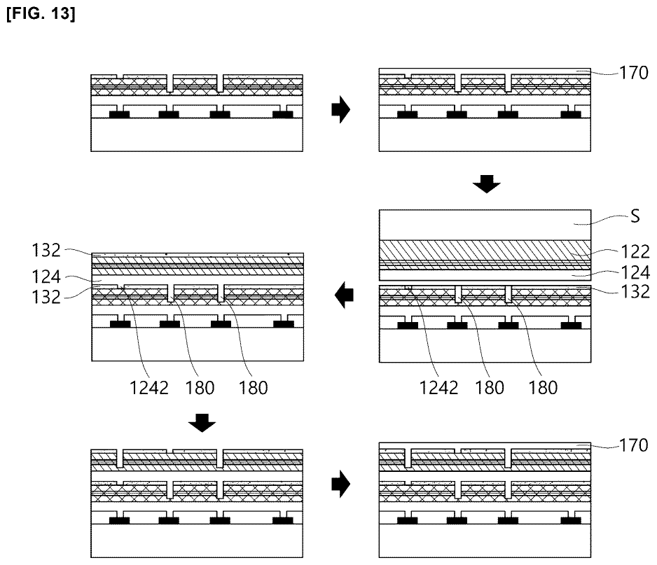

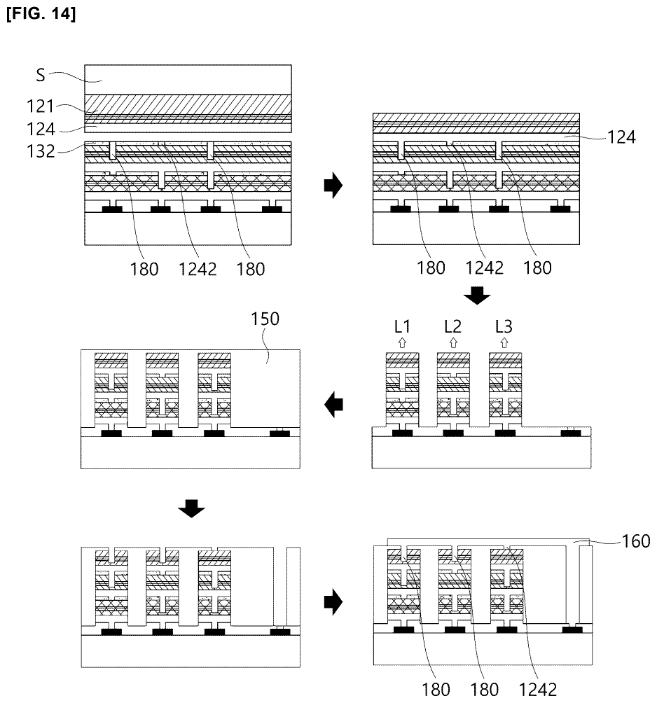

FIGS. 12 to 14 illustrate a case in which the first bonding layer is formed of a different material during a process of manufacturing a vertically stacked microdisplay panel according to the method of manufacturing a vertically stacked microdisplay panel according to one embodiment of the present invention.

Meanwhile, referring to FIGS. 12 to 14, the first bonding layer 131 of the present invention may be formed of a transparent electrically conductive material.

In this case, the first bonding layer 131 may be formed of a TCO that is identical or similar to that of the functional layer 124, and may be formed of, for example, a TCO material such as ITO, IZO, IMOO, or ITiO, a transparent conductive nitride (TCN) material such as TiN, or a transparent conductive oxynitride (TCON) material such as ITON, IZON, or TiNO, but the present invention is not limited thereto.

Specifically, in the first bonding operation, the first bonding layer 131 formed of a transparent electrically conductive material is formed on the back wafer 140, in which the CMOS electrode pad 141 is exposed to the outside, to be electrically connected to the CMOS electrode pad 141, and then the first bonding layer 131 is etched through MP or CMP to expose a surface of the passivation layer P therebelow.

In addition, although not shown, after the first bonding layer 131 is etched through MP or CMP, in some cases, the first bonding layer 131 may be vertically connected to the CMOS electrode pad 141 while being present with a uniform thickness on the electrically insulating passivation layer P on the back wafer 140.

Thereafter, in the first bonding operation, the functional layer 124 of the front wafer 110 and the passivation layer P of the back wafer 140 are bonded to each other, thereby bonding the front wafer 110 onto the back wafer 140.

In addition, although not shown, in some cases, the functional layer 124 of the front wafer 110 and the first bonding layer 131 of the back wafer 140 may be bonded to each other to bond the front wafer 110 onto the back wafer 140.

After the front wafer 110 is bonded to the back wafer 140, the support wafer S of the front wafer 110 is removed through LLO, CLO, or the like to expose a surface of the light-emitting portion 120 on which the functional layer 124 is not formed, that is, the surface of the second semiconductor region 1202. Thereafter, the second bonding layer 132 is formed on the surface, and subsequent processes are performed in the same manner as described above.

Accordingly, the light-emitting portion 120, the first bonding layer 131, the second bonding layer 132, and the functional layer 124 of the present invention are all transparent to transmit visible light, and thus there is an advantage in that there is no arrangement error issue in an exposure process. In addition, since a ceramic material is used rather than a metal, all of the first bonding layer 131, the second bonding layer 132, and the functional layer 124 of the present invention are easy to etch in a plasma dry process, and there is an advantage in that a problem of re-deposition of etch by-products does not occur.

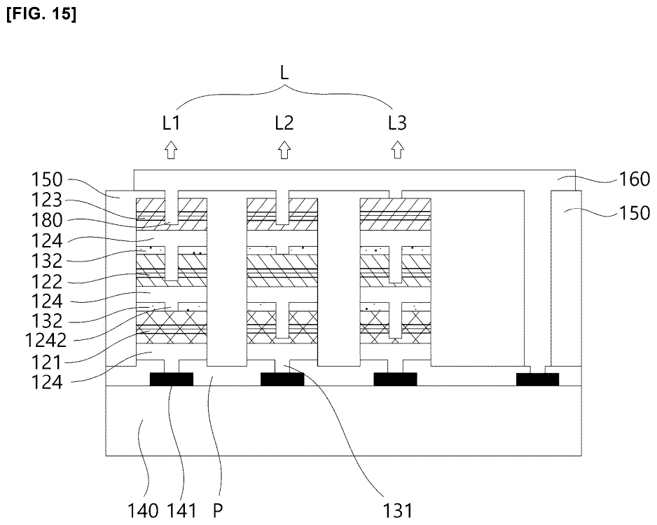

FIG. 15 illustrates a case in which the first bonding layer is formed of a different material in the vertically stacked microdisplay panel manufactured according to the method of manufacturing a vertically stacked microdisplay panel according to one embodiment of the present invention.

Referring to FIG. 15, the vertically stacked microdisplay panel 100 of the present invention includes the back wafer 140 having the plurality of CMOS electrode pads 141 arranged on the upper surface thereof, the plurality of LED stacks L which each include the plurality of light-emitting portions 120 vertically stacked through the bonding layer and are arranged on the plurality of CMOS electrode pads 141, and the common electrode 160 formed on the plurality of LED stacks L, wherein the bonding layer includes the first bonding layer 131 that bonds the light-emitting portion 120 onto the back wafer 140, and the second bonding layer 132 that bonds another light-emitting portion 120 onto the light-emitting portion 120 in a state in which the light-emitting portion 120 is bonded onto the back wafer 140 through the first bonding layer 131. Here, the first bonding layer 131 may be formed of a metallic material.

In this case, the functional layer 124 in ohmic contact with the light-emitting portion 120 is formed on one surface of the light-emitting portion 120, and a second bonding layer 132 formed of a transparent electrically insulating material is bonded to the functional layer 124 formed of a transparent electrically conductive material, thereby bonding another light-emitting portion 120 onto the light-emitting portion 120.

According to the present invention, unlike an existing monolithic integration method or hybrid method in which arrangement issues exist, an engineering monolithic epitaxy wafer is first manufactured, and then a stack on the engineering monolithic epitaxy wafer is etched and divided into preset units to arrange a plurality of LED stacks on a plurality of CMOS electrode pads. Therefore, not only a wafer with a small diameter of 6 inches or less, but also a wafer with a large diameter of 8 inches or more can be used so that the yield of a product can be significantly increased.

In addition, according to the present invention, high light transmittance, excellent electrical conductivity, and chemical and thermal stability can be secured through bonding between a transparent conductive material and a transparent insulating material, and at the same time, there are effects of improving the surface flatness of a bonding layer and improving bonding reliability between light-emitting portions.

Meanwhile, the effects of the present disclosure are not limited to the above-described effects, and various other effects can be included within a scope apparent to those skilled in the art from the description below.

While all of the components comprising embodiments of the present disclosure have been described above as combining or operating in combination, the present disclosure is not necessarily limited to these embodiments. In other words, any of the components may optionally operate in combination with one or more other components within the scope of the present disclosure.

In addition, terms such as “includes,” “consists of,” or “has” as used herein shall, unless specifically indicated to the contrary, be construed to mean that the component may be inherent in, and therefore may further include, other components, rather than exclude, other components. All terms, including technical or scientific terms, unless otherwise defined, shall have the same meaning as commonly understood by one of ordinary skill in the art to which this invention belongs. Commonly used terms, such as dictionary-defined terms, are to be interpreted consistent with their contextual meaning in the relevant art and are not to be construed in an idealized or overly formal sense unless expressly defined in the present disclosure.

The above description is merely an exemplary description of the technical spirit of the present disclosure, and those skilled in the art to which the present disclosure pertains will be able to modify and change the present disclosure in various ways without departing from the essential characteristics of the present disclosure.

Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed according to the appended claims, and all technical spirits within the equivalent range should be construed as being included in the scope of the present disclosure.

What is claimed is:

1. A vertically stacked microdisplay panel comprising:
a back wafer having an upper surface on which a plurality of complementary metal oxide semiconductor (CMOS) electrode pads are arranged;
a plurality of light-emitting diode (LED) stacks, each of which includes a plurality of light-emitting portions vertically stacked through a bonding layer and is arranged on one of the plurality of CMOS electrode pads; and
a common electrode formed on the plurality of LED stacks,
wherein the bonding layer includes a first bonding layer configured to bond the light-emitting portion onto the back wafer and a second bonding layer configured to bond another light-emitting portion onto the light-emitting portion in a state in which the light-emitting portion is bonded onto the back wafer through the first bonding layer, and
a short path is formed in at least one light-emitting portion of the plurality of light-emitting portions so that a current flows into the light-emitting portion in which the short path is not formed, and each of the plurality of LED stacks emits only light having a specific color.

2. The vertically stacked microdisplay panel of claim 1, wherein the first bonding layer is formed of a metallic material.

3. The vertically stacked microdisplay panel of claim 1, wherein the first bonding layer is formed of a transparent electrically conductive material.

4. The vertically stacked microdisplay panel of claim 1, wherein the second bonding layer is formed of a transparent electrically insulating material.

5. The vertically stacked microdisplay panel of claim 4, wherein a functional layer in ohmic contact with the light-emitting portion is formed on one surface of the light-emitting portion, and
the second bonding layer is bonded to the functional layer to bond the another light-emitting portion onto the light-emitting portion.

6. The vertically stacked microdisplay panel of claim 5, wherein the short path is formed to pass through the first bonding layer.

7. A method of manufacturing a vertically stacked microdisplay panel, the method comprising:
a preparation operation of preparing a front wafer including a support wafer and light-emitting portions, and a back wafer having an upper surface on which a plurality of complementary metal oxide semiconductor (CMOS) electrode pads are arranged;
a bonding operation of bonding the plurality of light-emitting portions onto the back wafer by repeating a process of bonding the front wafer onto the back wafer through a bonding layer and then removing the support wafer;
an etching operation of etching and dividing the plurality of stacked light-emitting portions and the bonding layer into preset units and arranging a plurality of light-emitting diode (LED) stacks on the plurality of CMOS electrode pads; and
a forming operation of forming a common electrode on the plurality of LED stacks,
wherein the bonding layer includes a first bonding layer configured to bond the light-emitting portion onto the back wafer, and a second bonding layer configured to bond another light-emitting portion onto the light-emitting portion in a state in which the light-emitting portion is bonded onto the back wafer through the first bonding layer, and
a short path is formed in at least one light-emitting portion of the plurality of light-emitting portions so that a current flows into the light-emitting portion in which the short path is not formed, and each of the plurality of LED stacks emits only light having a specific color.

8. The method of claim 7, wherein the first bonding layer is formed of a metallic material.

9. The method of claim 7, wherein the first bonding layer is formed of a transparent electrically conductive material.

10. The method of claim 7, wherein the second bonding layer is formed of a transparent electrically insulating material.

11. The method of claim 10, wherein a functional layer in ohmic contact with the light-emitting portion is formed on one surface of the light-emitting portion, and
the second bonding layer is bonded to the functional layer to bond the another light-emitting portion onto the light-emitting portion.

12. The method of claim 11, wherein the short path is formed to pass through the first bonding layer.
